(19) United States
(12) Patent Application Publication
(10) Pub. No.: US 2026/0251812 A1
(43) Pub. Date: Aug. 27, 2026

(54) MOTION HYPERPARAMETER CORRELATION AND SELECTION FOR NUCLEAR MAGNETIC RESONANCE (NMR) MOTION CORRECTION IN WELL SYSTEMS

(71) Applicant: Halliburton Energy Services, Inc., Houston, TX (US)

(72) Inventors: Boguslaw Wiecek, Houston, TX (US); Rebecca Jachmann, Houston, TX (US); Yunke Liu, Houston, TX (US); Jie Yang, Houston, TX (US); Arcady Reiderman, Richmond, TX (US)

(21) Appl. No.: 19/063,643

(22) Filed: Feb. 26, 2025

(51) Int. Cl. G01V 3/32; G01R 33/561; G01R 33/565; G01V 3/38; G06N 3/0985

(52) U.S. Cl. CPC G01V 3/32; G01R 33/5615; G01R 33/56509; G01V 3/38; G06N 3/0985

(57) ABSTRACT

Systems, methods, and apparatus, including computer programs encoded on computer-readable media, for obtaining nuclear magnetic resonance (NMR) measurements of a subsurface formation in a well system. NMR echo data having motion artifacts may be determined in response to performing downhole NMR measurements using an NMR tool. A motion indicator may be determined based on echo measurements performed using two or more acquisition windows within each of a plurality of echo waveforms of the NMR echo data. Motion data may be determined based on one or more non-NMR motion measurements obtained from one or more downhole well devices. A motion hyperparameter may be selected based on the motion data and a motion correlation mechanism. Corrected NMR echo data having reduced motion artifacts may be determined based on the motion indicator and the selected motion hyperparameter. Subsurface formation properties may be determined from the NMR echo data having reduced motion artifacts.

### TECHNICAL FIELD

The present invention relates generally to oil and gas systems and services, and more specifically to nuclear magnetic resonance (NMR) motion correction by motion hyperparameter correlation and selection in well systems.

### BACKGROUND

The oil and gas services industry uses various types of well equipment and tools in well systems at well sites. Well systems may use nuclear magnetic resonance (NMR) tools for NMR logging of the subsurface formation of a well for hydrocarbon reservoir evaluation. For example, the NMR logging may indicate various properties of the subsurface formation, such as the volume (e.g., porosity) and distribution (e.g., permeability) of the rock pore space, the rock composition, the type and quality of the fluids (e.g., water and hydrocarbons), and hydrocarbon producibility. NMR measurement data, such as NMR echo data, obtained from the NMR tool during NMR logging is sensitive to the motion of the NMR tool. For example, when the NMR tool is used in a logging while drilling (LWD) or a measurement while drilling (MWD) context, the longitudinal and lateral displacement due to the motion of the NMR tool can distort or introduce motion artifacts or noise into the NMR echo data. Since the motion of the NMR tool can distort or corrupt the NMR echo data, the analysis of the corrupted NMR echo data can result in the determination of inaccurate properties of the subsurface formation unless the corrupted NMR echo data is processed to reduce the motion artifacts.

### BRIEF DESCRIPTION OF THE DRAWINGS

FIG. 1 depicts a schematic diagram of an example well system including a nuclear magnetic resonance (NMR) tool, according to some implementations.

FIG. 2 depicts a workflow of example operations for reducing motion artifacts from NMR echo data by correlating and selecting a motion hyperparameter, according to some implementations.

FIG. 3A depicts an example echo waveform having two acquisition windows, according to some implementations.

FIG. 3B depicts an example plot including echo trains that are generated from the echo waveform measurements obtained from processing multiple acquisition windows, and the echo trains are used for determining a motion indicator, according to some implementations.

FIG. 4 depicts example plots that show a correlation between different motion measurements and an optimal motion hyperparameter, according to some implementations.

FIG. 5 depicts example plots that show motion profiles that can be used to build a motion correlation mechanism, according to some implementations.

FIG. 6 is a flowchart of example operations for obtaining NMR measurements of a subsurface formation in a well system, according to some implementations.

FIG. 7 depicts an example computer system of a well system for performing NMR measurements of a subsurface formation, according to some implementations.

FIG. 8 shows an example well system that includes an NMR tool in a wireline logging environment, according to some implementations.

FIG. 9 shows an example well system that includes an NMR tool in a drilling environment, according to some implementations.

FIG. 10 is a diagram of an example NMR magnet and antenna(s) configuration, according to some implementations.

### DESCRIPTION

The description that follows includes example systems, methods, techniques, and program flows that describe aspects of the disclosure. However, it is understood that this disclosure may be practiced without these specific details. For instance, this disclosure refers to certain well systems, devices, or tools in illustrative examples. Aspects of this disclosure can be instead applied to other types of well systems, devices, and tools. In other instances, well-known instruction instances, protocols, structures, and techniques have not been shown in detail to avoid confusion.

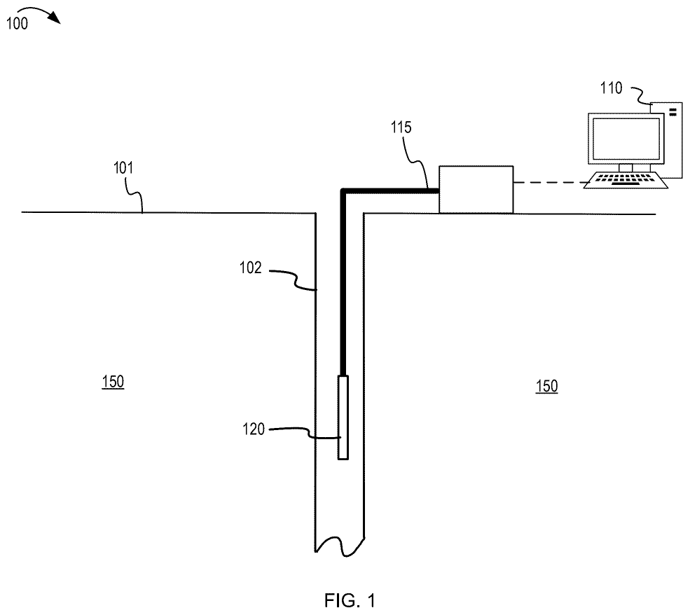

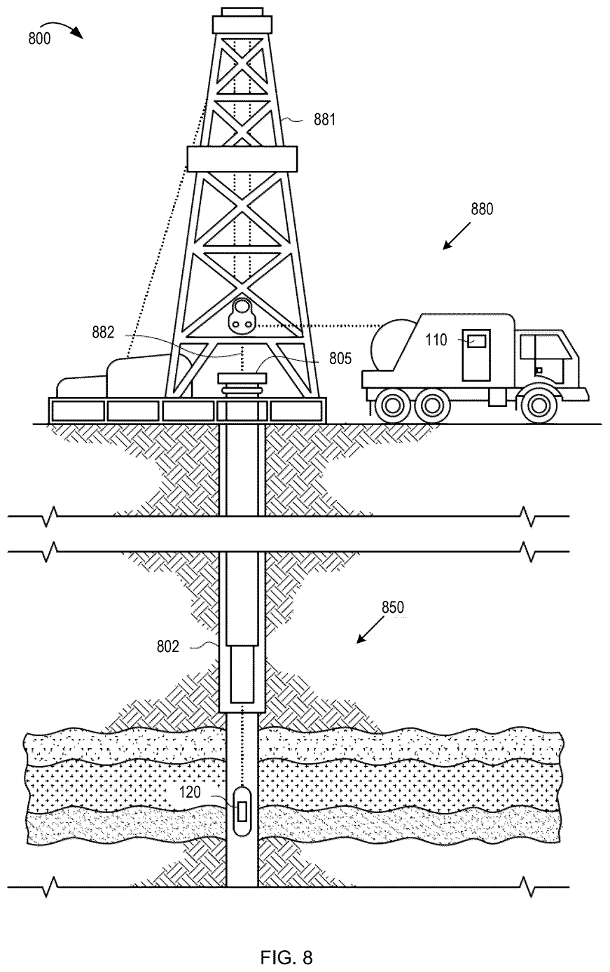

FIG. 1 depicts a schematic diagram of an example well system 100 including a nuclear magnetic resonance (NMR) tool, according to some implementations. In some implementations, the well system 100 may include a wellbore 102, surface equipment and tools, such as the computer system 110, and downhole equipment and tools, such as the NMR tool 120. The well system 100 may also include a cable 115 (e.g., a wireline) or other mechanism (such as a work string or drill string) that can lower the NMR tool 120 downhole into the wellbore 102 (or borehole). FIG. 1 shows a portion of the wellbore 102 and well system 100 for simplicity. It is noted that the well system 100 may include additional equipment, devices, tools and other components at the surface 101 or downhole that are not shown for simplicity. The well system 100 may use the NMR tool 120 for NMR logging of the subsurface formation 150 of the wellbore 102 for hydrocarbon reservoir evaluation. For example, the NMR logging may indicate various properties of the subsurface formation 150, such as the volume (e.g., porosity) and distribution (e.g., permeability) of the rock pore space, the rock composition, the type and quality of the fluids (e.g., water and hydrocarbons), and hydrocarbon producibility, among others. Therefore, the NMR measurements and other NMR data obtained from the NMR logging can be used for well site planning, well drilling, hydrocarbon recovery operations, and other well operations. Non-limiting examples of the well system 100 and the NMR tool 120 are further described in FIGS. 8-10.

In some implementations, the well system 100 may obtain NMR echo data from the NMR tool 120. The NMR echo data may be sensitive to the motion of the NMR tool 120 and thus the NMR echo data may include motion artifacts from the downhole motion of the NMR tool 120. For example, when the NMR tool 120 is used in a logging while drilling (LWD) or a measurement while drilling (MWD) context, the longitudinal and lateral displacement due to the motion of the NMR tool 120 can distort, corrupt, or introduce motion artifacts into the NMR echo data. The motion artifacts may also be referred to as motion-based noise or motion noise. Since the motion of the NMR tool 120 can distort or corrupt the NMR echo data, the corrupted NMR echo data may lead to inaccurate results, such as the determination of inaccurate properties of the subsurface formation. For at least these reasons, the well system 100 may reduce the motion artifacts of the NMR echo data by correlating and selecting a motion hyperparameter before further processing the NMR echo data to determine the subsurface formation properties, as further described below.

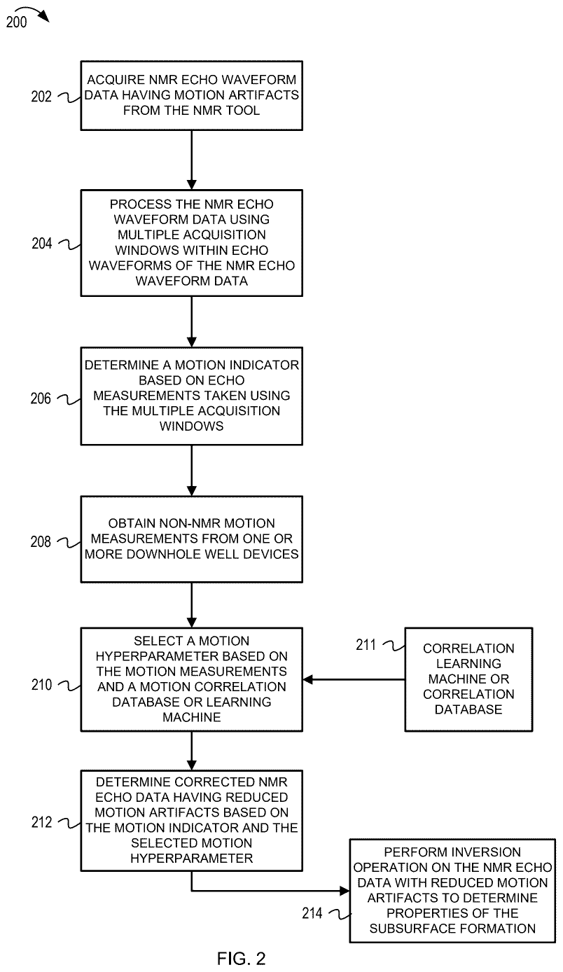

FIG. 2 depicts a workflow 200 of example operations for reducing motion artifacts from NMR echo data by correlating and selecting a motion hyperparameter, according to some implementations. In some implementations, the well system 100 may acquire NMR echo waveform data having motion artifacts from the NMR tool 120 (block 202). For example, the computer system 110 (or other type of surface equipment or computing device) of the well system 100 may obtain the NMR echo waveform data with motion artifacts from the NMR tool 120. The NMR echo waveform data with motion artifacts are NMR echo waveforms with motion artifacts. The NMR echo waveform data having motion artifacts may generally be referred to as NMR echo data having motion artifacts.

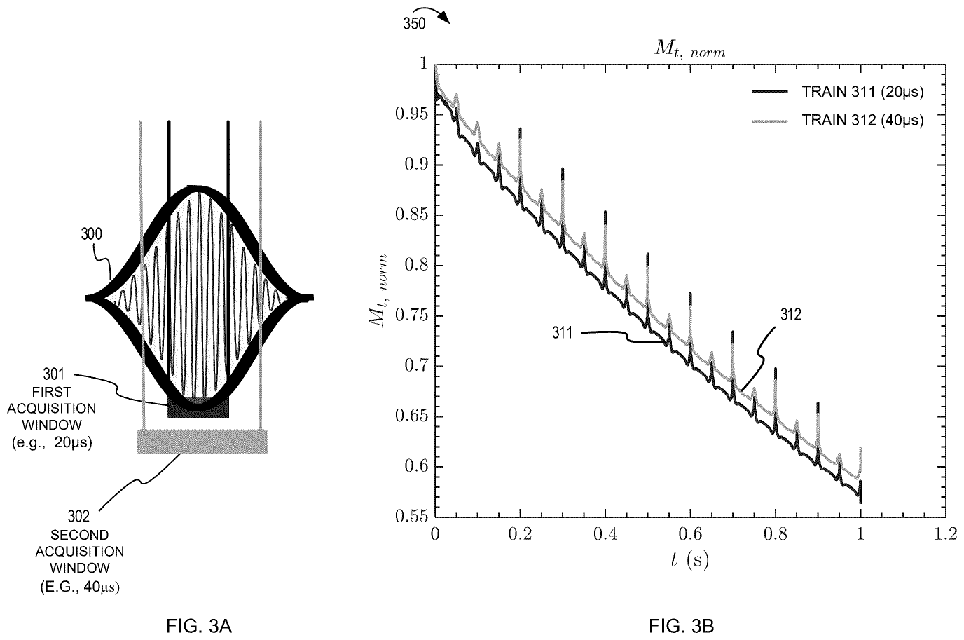

In some implementations, the well system 100 may process the NMR echo waveform data using multiple acquisition windows within one or more echo waveforms of the NMR echo waveform data (block 204). As further described below, the NMR echo waveform data may be processed using multiple acquisition windows within one or more echo waveforms to generate multiple echo trains. The NMR echo waveform data typically includes numerous echo waveforms. FIG. 3A depicts an example echo waveform 300 having two acquisition windows. In some implementations, first echo measurements may be performed using a first acquisition window 301 within the echo waveform 300 and second echo measurements may be performed using a second acquisition window 302 within the echo waveform 300. For example, the first acquisition window 301 may be 20 μs and the second acquisition window 302 may be 40 μs. It is noted, however, that the acquisition windows may be of any size within the echo waveform 300. The echo measurements using the two acquisition windows may be repeated for additional echo waveforms of the NMR echo waveform data (which may also be referred to as NMR echo data). As shown in plot 350 of FIG. 3B, after taking the echo measurements using the acquisition windows, an echo train 311 is generated from the echo measurements taken using the first acquisition window 301 across multiple echo waveforms (including the echo waveform 300), and an echo train 312 is generated from the echo measurements taken using the second acquisition window 312 across multiple echo waveforms (including the echo waveform 300).

In some implementations, the well system 100 may determine a motion indicator (MI) based on the echo measurements taken using the multiple acquisition windows (block 206). For example, the motion indicator may be determined based on the echo measurements taken using the first acquisition window 301 and using the second acquisition window 302 across multiple echo waveforms. As shown in FIG. 3B, since different motion takes place during different time periods of the echo waveforms that correspond to the different acquisition windows, the resulting echo trains 311 and 312 have slightly different motion artifacts (or motion artifact signatures). A non-limiting example algorithm for determining the motion indicator is described below. As described below, the motion indicator can use properties that are common to both the echo trains 311 and 312 to analyze the slightly different motion artifacts of the echo trains 311 and 312 and determine a motion indicator from this analysis of the relationship between the echo train data from the two different acquisition windows.

In some implementations, the well system 100 may obtain non-NMR motion measurements from one or more downhole well devices (block 208). For example, acceleration measurements may be obtained from one or more accelerometers, position or other acoustic measurements can be obtained from one or more acoustic tools, or other motion measurements can be obtained from one or more other devices. For example, the motion measurements may provide motion related data such as frequency, phase, and/or amplitude, among others.

In some implementations, the well system 100 may select a motion hyperparameter based on the non-NMR motion measurements and a motion correlation database or learning machine (blocks 210 and 211). The motion correlation database and/or the motion correlation learning machine may be referred to as a motion correlation mechanism. The motion correlation database (e.g., including a correlation lookup table and/or a correlation equation or formula) or motion correlation learning machine (e.g., implements machine learning and/or neural network) can correlate non-NMR motion measurements with motion hyperparameters. For example, for any obtained non-NMR motion measurement, the motion correlation database or motion correlation learning machine can use a predetermined correlation to correlate the non-NMR motion measurement to the best or optimal motion hyperparameter that can be used with the motion indicator to reduce the motion artifacts of the NMR echo data, as further described below. A non-limiting example algorithm that uses the motion indicator and the motion hyperparameter to reduce motion artifacts from the NMR echo data is described below. In some implementations, the motion hyperparameter selected from the correlation can be used with the motion indicator to derive a motion multiplier (MM) that can be used to reduce motion artifacts from the NMR echo data, as described further below.

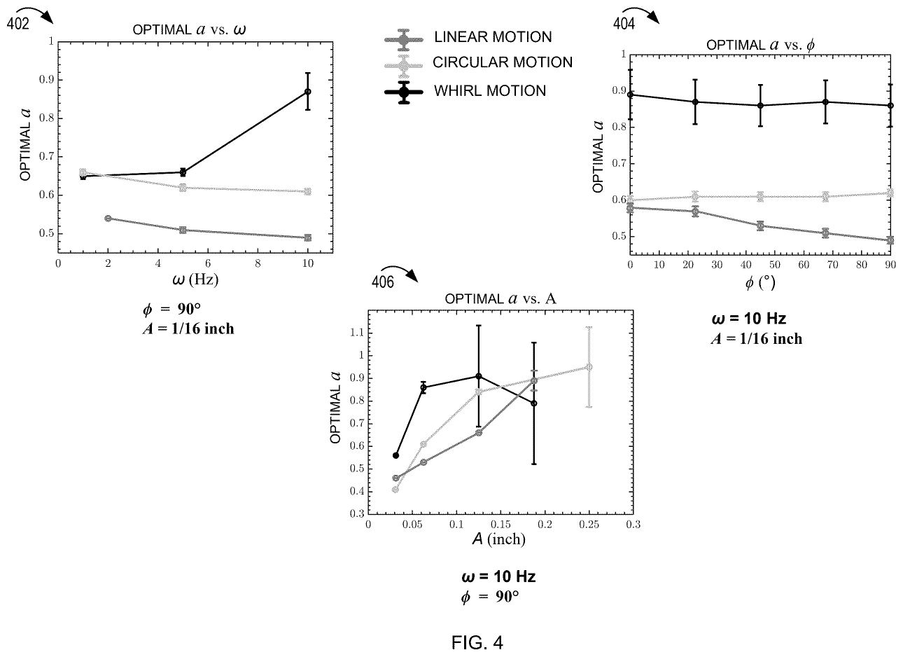

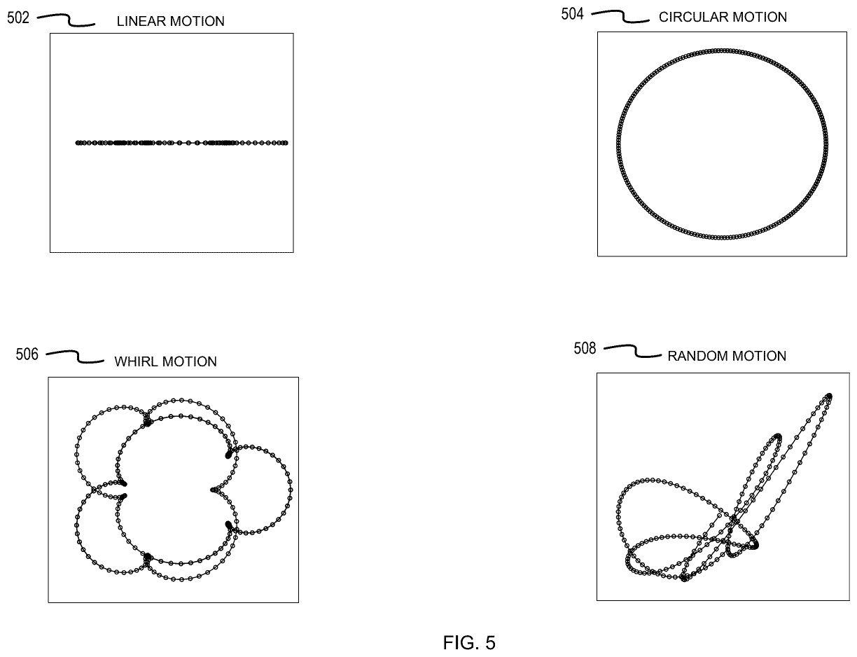

In some implementations, during a preparation or calibration or training stage, the motion correlation database (e.g., including a lookup table) or motion correlation learning machine (e.g., implements machine learning and/or neural network) can determine, prepare (or test/train), build, and/or store the correlation between the non-NMR motion measurements and the motion hyperparameter. In some implementations, for a selected known motion (e.g., a motion measurement) from numerous types of known motion, forward modeling can be performed with the selected known motion and known NMR echo trains with the corresponding motion artifacts. For example, a spin dynamics simulator can be used to synthetically generate the known NMR echo train with the known motion artifacts, and measurements can be taken using two or more acquisition windows (i.e., similar to the process that is performed on real or field echo data). Since the motion is known, and the NMR echo train having motion artifacts is known, the result of how to reduce the motion artifacts is known. From there, since the results are known, the modeling can determine which is the best or optimal motion hyperparameter for the known motion that achieves the desired and known results. By doing this, the motion hyperparameter that is optimal to achieve the desired and know results (e.g., reduced motion artifacts for the NMR echo train) can be correlated with the known motion. Additional models can be run for a multitude of possible motions (e.g., numerous motion measurements) to build a database and/or lookup table and/or equation/function that correlates each of the motion measurements with the motion hyperparameters. For example, the various motion measurements may be different accelerometer measurements or acoustic measurements or other motion related measurements, such as different frequency values, phase values, or amplitude values, among others. In some implementations, instead of or in addition to a database and/or lookup table and/or equation, a learning machine may implement machine learning and/or neural network to train and build the motion correlation mechanism that correlates each of the motion measurements with the motion hyperparameters. FIG. 4 depicts example plots that show a correlation between different motion measurements and an optimal motion hyperparameter. In plot 402, when the phase and amplitude stays constant but the frequency measurements vary, the plot 402 shows the correlation between the frequency and the motion hyperparameter for different motion profiles, such as a linear motion profile, a circular motion profile, and a whirl motion profile. In plot 404, when the frequency and amplitude stays constant but the phase measurements vary, the plot 404 shows the correlation between the phase and the motion hyperparameter for the different motion profiles. In plot 406, when the frequency and phase stays constant but the amplitude measurements vary, the plot 406 shows the correlation between the phase and the motion hyperparameter for the different motion profiles. FIG. 5 depicts example plots that show some of the motion profiles that can be used to build the correlation information and/or for test and training purposes. For example, plot 502 shows an example linear motion profile, plot 504 shows an example circular motion profile, plot 506 shows an example whirl motion profile, and plot 508 shows an example random motion profile.

Returning to FIG. 2, after selecting the motion hyperparameter, in some implementations, the well system 100 may determine the corrected NMR echo data having reduced motion artifacts based on the motion indicator and the selected motion hyperparameter (block 212). In some implementations, the motion indicator and the selected motion hyperparameter can be used to derive a motion multiplier. The motion multiplier can be used to reduce the motion artifacts of the NMR echo data to generate the corrected NMR echo data with reduced motion artifacts. A non-limiting example algorithm that derives the motion multiplier (MM) from the motion indicator (MI) and the selected motion hyperparameter and uses the motion multiplier to reduce motion artifacts is described below.

In some implementations, the well system 100 may utilize the NMR echo data (e.g., the NMR echo train) with reduced motion artifacts for determining properties of the subsurface formation and performing well operations based on the properties. In some implementations, the well system 100 may perform an inversion operation on the NMR echo data (e.g., the NMR echo train data) with reduced motion artifacts to determine the properties of the subsurface formation (block 214). For example, a non-negative least square inversion algorithm Y=AX can be performed on the NMR echo data with reduced motion artifacts, or a multi-dimensional inversion operation (or other types of inversion operations) can be performed on the NMR echo data with reduced motion artifacts. After reducing the motion artifacts, the NMR echo data be used by various tools and products and services for NMR logging and well-related tasks. The well system 100 may use the NMR echo data with reduced motion artifacts and other NMR measurements for NMR logging of the subsurface formation of the wellbore for hydrocarbon reservoir evaluation. For example, the NMR logging may indicate various properties of the subsurface formation, such as the volume (e.g., porosity) and distribution (e.g., permeability) of the rock pore space, the rock composition, the type and quality of the fluids (e.g., water and hydrocarbons), and hydrocarbon producibility, among others. Therefore, the NMR measurements and other data obtained from the NMR logging can be used for well site planning, hydrocarbon recovery operations, and other well operations. In some implementations, well operations associated with the subsurface formation (e.g., such as drilling the well or hydrocarbon recovery) can be determined or modified based on the properties of the subsurface formation derived from the NMR measurements, such as the NMR echo data with reduced motion artifacts.

As described above in FIG. 2, the motion hyperparameter correlation and selection operations can be used to reduce motion artifacts in NMR echo data. A non-limiting example of an algorithm for performing the operations of FIG. 2 is described below.

In some implementations, in order to gauge the perturbation of echo waveforms from motion, an algorithm or method of determining motional information is described herein. Each echo train data set is different with different motions. The spins are sensitive to magnetic field strength which changes as the tool moves. The result is data which contains losses due to sensitivity to motion. These losses in the data are a distinction from the decay (e.g., T2 decay). The aspect of which NMR measurement can be made dependent on motion is by changing the acquisition window. Because of this a motion indicator can be made by using multiple acquisition windows. In some implementations, a motion indicator (MI) can be created with a single acquisition sequence by creating several echo trains, where each echo train from the singular acquisition sequence has a different acquisition window. For the train sequence k, a number of echo trains, numbered with the index n, can be created as shown below in Equation 1.1. In Equation 1.1, Yₖₙ (t, Wₙ) is the kth echo train with acquisition window Wₙ produced by echo waveforms. Each echo waveform is transformed into a single point called an echo using a specified acquisition window. The resulting group of echoes, usually a vector or matrix, is called the echo train.

$${Y}_{k n} ( t , {W}_{n} ) = \{ 1 - {δ}_{n} [ {W}_{n} , {d}_{k} ( t ) ] \} \cdot {\sum }_{i} {X}_{i} \cdot exp ( - \frac{t}{{T}_{2 i}} ) \qquad ( Equation 1.1 )$$

In some implementations, from the multiple sets of echo trains, motion indicators can be created as shown in Equation 1.2. Equation 1.2 creates an example motion indicator with a natural log; however, the motion indicator is not limited to this form. It can also be made without it. In some implementations, motion indicators can be determined by calculating the natural logarithm of the ratio of two echo trains with two acquisition windows or simply by computing the ratio itself. In this example, the two echo trains have the same echo spacing and therefore the echoes occur at the same time, t. However, they have separate acquisition windows, Wₙ, e.g., two separate acquisition windows.

$${MI}_{k} ( t , {W}_{1 , 2} ) = - ln [ \frac{{{Y}_{k 1} ( t , {W}_{1} )}_{M}}{{{Y}_{k 2} ( t , {W}_{2} )}_{M}} ] \qquad ( Equation 1.2 )$$

In order to simplify the equations used herein, the expression δ_{N}[Wₙ,dₖ (t)]≡δₖₙ can be used. And since ln(1+x)≈(1+x)−1=x when x is small, and when considering RMS(δ_{Ok})<<1 & RMS (δ_{Mk})<<1, then the following Equation 1.3 can be derived.

$${MI}_{k} ( t , {W}_{1 , 2} ) = - ln [ \frac{{{Y}_{k 1} ( t , {W}_{1} )}_{M}}{{{Y}_{k 2} ( t , {W}_{2} )}_{M}} ] \approx {δ}_{1 k} - {δ}_{2 k} \qquad ( Equation 1.3 )$$

When there is a relationship between the echo train of a first acquisition window and the echo train of a second acquisition window, the relationship can be written as a change of the motional error that is observed in each train, such that δ₂ₖ=F (δ₁ₖ).

In some implementations, the transfer function which relates them could be expanded using a Taylor function, or any other expansion function. One example of the Taylor expansion may be shown as follows.

$$F ( {δ}_{1 k} ) \approx {a}_{1} \cdot {δ}_{1 k} + {a}_{2} \cdot {( {δ}_{1 k} )}^{2} + … \qquad ( Equation 1.4 )$$

The aᵢ is the motion hyperparameter and is dependent on the motion. If only the first order is considered, the equation may be simplified as follows.

$${δ}_{M k} = F ( {δ}_{O} ) \approx a \cdot {δ}_{1 k} \qquad ( Equation 1.5 )$$

Then, substituting δ₂ₖ into the motion indicator MIₖ, the motion indicator MIₖ can be shown as follows.

$${MI}_{k} \approx ( 1 - a ) \cdot {δ}_{1 k} \qquad ( Equation 1.6 )$$

After solving for δ₁ₖ, δ₁ₖ can be expressed as shown below based on the motion indicator MIₖ and the motion hyperparameter aᵢ.

$${δ}_{1 k} \approx \frac{{MI}_{k}}{( 1 - a )} \qquad ( Equation 1.7 )$$

In some implementations, the motion indicator MIₖ and the motion hyperparameter aᵢ (e.g., Equation 1.7) may be used to derive a motion multiplier, MM (which may also be referred to as a motion factor), which can be used to correct the motion (e.g., reduce the motion artifacts) of the original echo waveform. In some implementations, the Equation 1.7 can be substituted into an equation for the motion multiplier (MM) as shown below.

$$M = \frac{1}{MM} = 1 - {δ}_{1 k} = 1 - \frac{{MI}_{k}}{( I - a )} \qquad ( Equation 1.8 )$$

$$MM = \frac{1 - a}{1 - a - {MI}_{k}} \qquad ( Equation 1.9 )$$

In some implementations, the motion multiplier, MM, can be used to correct the motion of the original echo waveforms.

$$( Equation 1.1 )$$

$${Y}_{k 1} ( t , {W}_{1} ) = {{Y}_{k 1} ( t , {W}_{1} )}_{M} \cdot MM = {{Y}_{k 1} ( t , {W}_{1} )}_{M} \cdot \frac{1 - a}{1 - a - {MI}_{k} ( y , {W}_{1 , 2} )}$$

In some implementations, the value of the motion hyperparameter a may be dependent on the dimensionality of the motion, the phase of the motion, the frequency of the motion, the amplitude of the motion, the echo time (TE) of the sequence, and the acquisition window selection. For correcting the motion of an echo waveform (e.g., the motion artifacts), a dynamic motion hyperparameter a can be used which changes with the motion, and therefore the motion hyperparameter a can be correlated with different motion measurements or other motion characteristics. In some implementations, building a database (e.g., a lookup table) for the correlation between the motion hyperparameter and the motion parameters or measurements can be achieved by simulation of spin dynamics or by running extensive tests on the NMR tool which will be used. For example, the user selects the TE and the acquisition windows for table selection for these variations. However, the downhole environment could have a great number of motion amplitude, phases, and frequencies variations. The motion can also differ in the amount of single dimensionality versus double dimensionality. In some implementations, accelerometers or acoustic measurements can be used to obtain non-NMR motion measurements and identify the motion. The motion measurement can identify the motion's amplitude, frequence, and/or phase. The measurement of the motion may also identify the motion profile, such as if the motion is linear, circular, whirl, or other random motion profiles. Once the motion is identified, the optimal motion hyperparameter a can be selected and used along with the MI for the calculation of MM. Then, the calculated MM may be used to correct the for the motion.

In some implementations, the well system 100 may use a learning machine (such as a machine learning model, a machine learning neural network, or other suitable particularized machine) to receive the inputs, perform the operations, and generate the outputs described in FIG. 2. In some implementations, the operations described above in FIG. 2 that use mathematical models may instead be performed by a learning machine (or some combination of mathematical models and a learning machine) to receive the input (e.g., acquire NMR echo data having motion artifacts), perform the motion hyperparameter correlation and selection operations described in FIG. 2, and generate an output (e.g., NMR echo data with reduced motion artifacts). In some implementations, the learning machine or the machine learning model may include computer code and/or a neural network and be implemented on a non-transitory computer readable medium, circuitry, and/or any other logic components configured to perform the operations described herein.

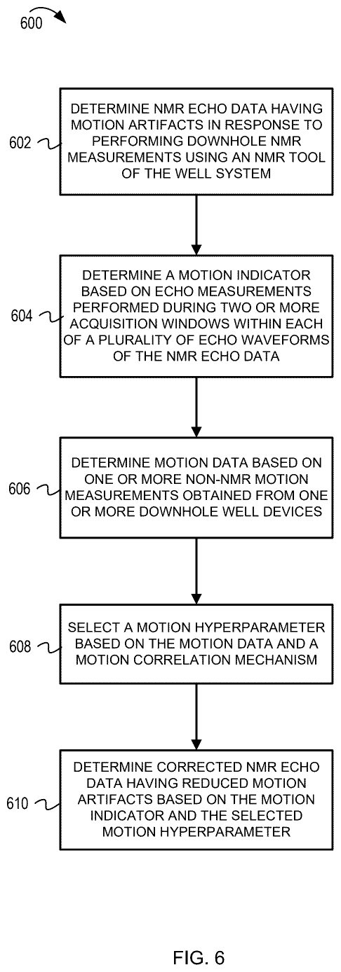

FIG. 6 is a flowchart 600 of example operations for obtaining nuclear magnetic resonance (NMR) measurements of a subsurface formation in a well system, according to some implementations. In some implementations, NMR echo data having motion artifacts may be determined in response to performing downhole NMR measurements using an NMR tool of the well system (block 602). In some implementations, a motion indicator may be determined based on echo measurements performed using two or more acquisition windows within each of a plurality of echo waveforms of the NMR echo data (block 604). In some implementations, motion data may be determined based on one or more non-NMR motion measurements obtained from one or more downhole well devices (block 606). In some implementations, a motion hyperparameter may be determined based on the motion data and a motion correlation mechanism (block 608). In some implementations, corrected NMR echo data having reduced motion artifacts may be determined based on the motion indicator and the selected motion hyperparameter (block 610).

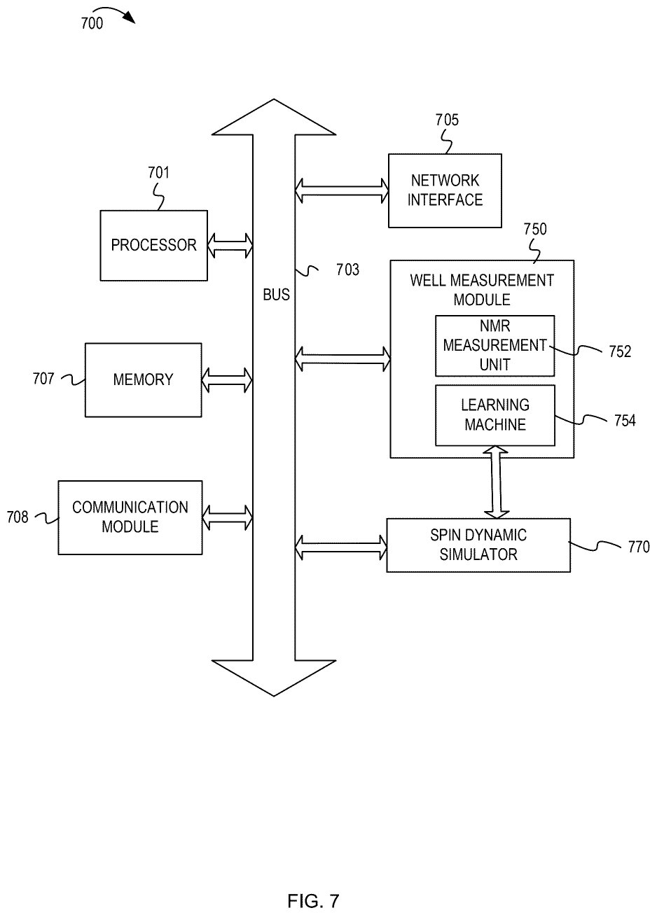

FIG. 7 depicts an example computer system of a well system for performing NMR measurements of a subsurface formation, according to some implementations. In some implementations, the computer system 700 may be an example of a computer system that may be used during the operation of the well system, such as the computer system 110 shown in FIG. 1. For example, the computer system 700 may be a standalone computer system (such as a workstation, laptop, or desktop), or may be partially or fully integrated into other surface equipment of the well system (e.g., control panel or truck). In some implementations, the computer system 700 may be implemented partially or fully in downhole components of the well system (e.g., within the NMR tool and/or work string and/or well tubing) or the computing functions of the computer system 700 may be distributed across both downhole components (e.g., NMR tool and/or work string) and surface equipment (e.g., workstation or other computer subsystem). The computer system 700 may include one or more processors 701 (possibly including multiple cores, multiple nodes, and/or implementing multi-threading, etc.). The computer system 700 may include memory 707. The memory 707 may be system memory or any type or implementation of machine or computer readable media having instructions that are executable by the one or more processors 701 to implement the operations described in FIGS. 1-6. The memory 707 may be system memory or any type or implementation of machine or computer readable and writable media having the ability to receive, process and/or store measurement data from well devices and tools (including those described in FIGS. 1-6). The computer system 700 also may include a bus 703 and a network interface 705. The computer system 700 also may include a communications module 708 that may control wired and wireless communications, such as communicating with downhole devices or tools and communicating with other surface equipment. The computer system 700 also may include at least a well measurement module 750 and a spin dynamic simulator 770, among other processing units or modules that are used during the operation of the well system and the well tools described herein (not shown for simplicity). The well measurement module 750 may include an NMR measurement unit 752 and a learning machine 754. In some implementations, the NMR measurement unit 752 may control above ground and downhole equipment and tools to obtain measurement data, such as controlling an NMR tool that can take NMR measurements downhole of a subsurface formation for NMR logging, as described in FIGS. 1-6. The NMR measurement unit 752 may also cause the NMR tool to generate NMR pulses and may receive, process and analyze NMR measurements, such as NMR echo data. In some implementations, the NMR measurement unit 752 may perform the operations described above in FIGS. 1-6 for obtaining NMR echo data, performing echo measurements on two or more acquisition windows, determining a motion indicator, obtaining non-NMR motion measurements, implementing a motion correlation mechanism for selecting a motion hyperparameter, and generating NMR echo data with reduced motion artifacts. In some implementations, the NMR measurement unit 752 may implement the motion correlation mechanism (that correlates non-NMR motion measurements with motion hyperparameters) via a database having a motion correlation lookup table or a motion correlation equation/function, as described above in FIGS. 1-6. In some implementations, the learning machine 754 (or a machine learning model) may include computer code and/or a neural network (such as the neural network described above in FIGS. 1-6) and be implemented on a non-transitory computer readable medium, circuitry, and/or any other logic components configured to perform the operations described above in FIGS. 1-6. The learning machine 754 may learn, train and implement the motion correlation mechanism that correlates non-NMR motion measurements with motion hyperparameters. The spin dynamic simulator 770 may generate synthetic NMR echo data and synthetic motion data to train and test the learning machine 754 that implements the motion correlation mechanism and/or to build a motion correlation lookup table or equation. In some implementations, the well measurement module 750 may work in conjunction with the spin dynamic simulator 770 to train and test the learning machine 754 or to build the motion correlation lookup table or equation. In some implementations, the NMR measurement unit 752 (in conjunction with other control and processing units of the computer system 700) may utilize the NMR measurement data (e.g., NMR echo data) for determining properties of the subsurface formation and performing and/or modifying well operations (or well parameters/attributes) based on the determined properties of the subsurface formation, as described above. The functionality described herein may be implemented with an application-specific integrated circuit, in logic implemented in the processor(s) 701, in a co-processor on a peripheral device or card, etc. Further, implementations may include fewer or additional components not illustrated in FIG. 7. The processor(s) 701 and the network interface 705 may be coupled to the bus 703. Although illustrated as being coupled to the bus 703, the memory 707 may be coupled to the processor(s) 701.

NMR logging is possible because when an assembly of magnetic spins, such as those of hydrogen nuclei spins, are exposed to a static magnetic field they tend to align along the direction of the magnetic field, resulting in bulk magnetization. The rate at which equilibrium is established in such bulk magnetization upon provision of a static magnetic field is characterized by the parameter T1, referred to as the spin-lattice relaxation time. Another related NMR logging parameter is T2, referred to as the spin-spin relaxation time constant (also referred to as the transverse relaxation time), which is an expression of the relaxation due to nuclear spins dephasing. NMR logging has two main experiments in oil field downhole usage. The first experiment is to assess T1 buildup of magnetization, and the second experiment is to observe the decay of magnetization once it has been excited, in which the decay has a time constant of T2.

Measurement of T1 is indirect and is done by varying the polarization times after magnetization has, through some means, been nullified or inverted. For downhole observation, an NMR measurement technique, designed by Carr, Purcell, Meiboom, and Gill and, hence, referred to as CPMG, is used. It is considered a T2 measurement. As described previously, CPMG has an excitation pulse followed by several refocusing pulses to counter the magnetic gradients in downhole NMR systems. A T1 sequence is typically performed as: Nullification Pulse-WaitTime-Excitation Pulse-Refocusing pulses. In some cases, the T1 sequence has several different wait times. The number of refocusing pulses may be as few as 3 and as many as associated electronics are configured to handle (e.g., acquire and/or process).

A portion of hydrogen nuclei spins in the earth formation are, in the aggregate, caused to be aligned with the magnetic field induced in the earth formation by a magnet and result in a net magnetization of the formation. The NMR tool (e.g., such as the NMR tool 120 in FIG. 1) also includes an antenna positioned near the magnet and shaped so that a pulse of RF power conducted through the antenna induces a magnetic field in the earth formation substantially orthogonal to the field induced by the magnet. A receiving antenna (which may be the same antenna as the one that generates the initial RF pulse) is electrically connected to a receiver, which detects and measures voltages induced in the receiving antenna by precessional motion of the nuclear spins.

An NMR measurement involves a plurality of pulses grouped into pulse sequences, most frequently of a type known as CMPG pulsed spin echo sequences. Each CPMG sequence consists of an excitation pulse, which may be a 90-degree (i.e., π/2) pulse, followed by several refocusing pulses, which may be 180-degree (i.e., π) rotation pulses. The excitation pulse rotates the proton spins into the transverse plane and the refocusing pulses generate a sequence of spin echoes by refocusing the transverse magnetization after each spin echo defocuses.

NMR well logging data are sensitive to motion of the NMR tool. In an example in which the NMR tool is used in a logging while drilling (LWD) or a measurement while drilling (MWD) context, a lateral motion (e.g., vibration) and rotational movement of drilling operations may cause distortion of the NMR well logging data and, in some cases, an inability to acquire a spin echo signal representing transversal NMR relaxation (i.e., T2 relaxation).

While rotational sensitivity may be reduced by designing the NMR tool to be essentially axially symmetrical, the longitudinal and lateral displacement due to NMR tool motion (e.g., vibration), such as while drilling, remains problematic for NMR data acquisition in a LWD or MWD context.

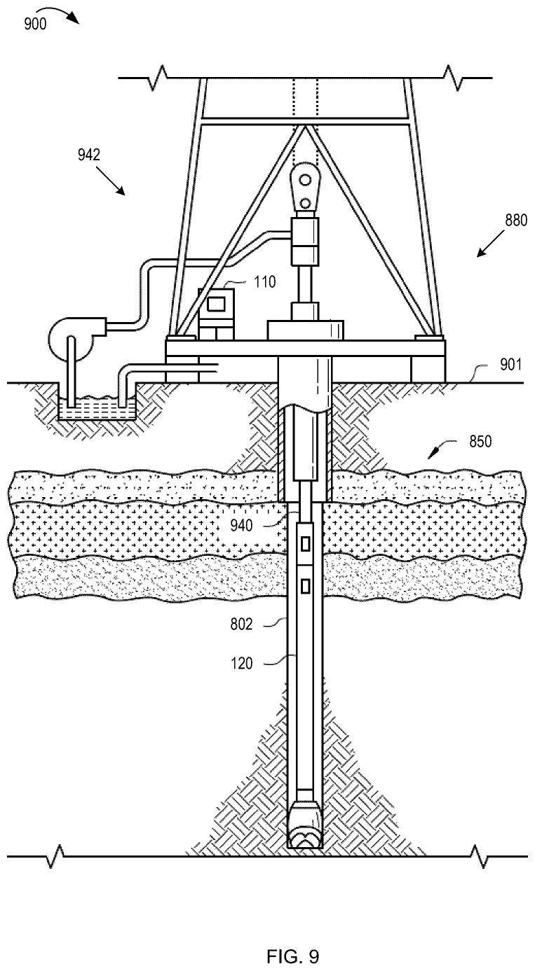

In some implementations, the NMR logging operations can be performed in connection with various types of downhole operations at various stages in the lifetime of a well system. Structural attributes and components of the surface equipment and NMR tool can be adapted for various types of NMR logging operations. For example, NMR logging may be performed during wireline logging operations (e.g., see FIG. 8), during drilling operations (e.g., see FIG. 9), or in other contexts. Accordingly, the surface equipment and the NMR tool may include, or may operate in connection with drilling equipment, wireline logging equipment, or other equipment for other types of operations. As another example, NMR logging may be performed in an offshore or subsea environment. Accordingly, the surface equipment may be arranged on a drill ship or other offshore drilling vessel, and the NMR tool operates in connection with offshore drilling equipment, offshore wireline logging equipment, or other equipment for use with offshore operations.

FIG. 8 shows an example well system 800 that includes the NMR tool 120 in a wireline logging environment, according to some implementations. The NMR tool 120 may be an example of the NMR tool 120 shown in FIG. 1. In some example wireline logging operations, the surface equipment 880 may include a platform above the surface equipped with a derrick 881 that supports a wireline cable 882 that extends into the wellbore 802 through the wellhead 805. Wireline logging operations can be performed, for example, after a drill string is removed from the wellbore 802, to allow the NMR tool 120 to be lowered by wireline or logging cable into the wellbore 802.

FIG. 9 shows an example well system 900 that includes the NMR tool 120 in a drilling environment, according to some implementations. For example, the drilling environment may include performing logging while drilling (LWD) operations or a measurement while drilling (MWD) operations. The NMR tool 120 may be an example of the NMR tool 120 shown in FIG. 1. Drilling is commonly carried out using a string of drill pipes connected together to form a drill string 940 that is lowered through a rotary table into the wellbore 802. In some cases, a drilling rig 942 at the surface 901 supports the drill string 940, as the drill string 940 is operated to drill a wellbore penetrating the subsurface formation 850. The drill string 940 may include, for example, a kelly, drill pipe, a bottomhole assembly, and other components. The bottomhole assembly on the drill string may include drill collars, drill bits, the NMR tool 120, and other components, including additional logging tools. The additional logging tools may include MWD tools, LWD tools, and others.

In some implementations, the NMR tool 120 is configured to obtain NMR measurements from the subsurface formation 850. As shown, for example, in FIG. 8, the NMR tool 120 can be suspended in the wellbore 802 by a coiled tubing, wireline cable, or another structure that connects the tool to a surface control unit or other components of the surface equipment 880. In some example implementations, the NMR tool 120 is lowered to the bottom of a region of interest and subsequently pulled upward (e.g., at a substantially constant speed) through the region of interest. As shown, for example, in FIG. 9, the NMR tool 120 can be deployed in the wellbore 802 on jointed drill pipe, hard wired drill pipe, or other deployment hardware. In some example implementations, the NMR tool 120 collects data (e.g., measurement data) during drilling operations as it moves downward through the region of interest. In some example implementations, the NMR tool 120 collects data while the drill string 940 is moving, for example, while it is being tripped in or tripped out of the wellbore 802.

In some implementations, the NMR tool 120 collects data at discrete logging points in the wellbore 802. For example, the NMR tool 120 can move upward or downward incrementally to each logging point at a series of depths in the wellbore 802. At each logging point, instruments in the NMR tool 120 perform measurements on the subsurface formations 850. The measurement data can be communicated to the computer system 110 for storage, processing, and analysis. Such data may be gathered and analyzed during drilling operations (e.g., during LWD/MWD operations), during wireline logging operations, or during other types of activities. The computer system 110 shown in FIGS. 8 and 9 may be configured to receive and analyze the measurement data from the NMR tool 120 to detect properties of the subsurface formation 850, as previously described above in FIG. 1.

In some implementations, the NMR tool 120 obtains NMR signals by polarizing nuclear spins in the subsurface formation 850 and pulsing the nuclei with a radio frequency (RF) magnetic field. Various pulse sequences (i.e., series of radio frequency pulses, delays, and other operations) can be used to obtain NMR signals, including the CPMG sequence (in which the spins are first tipped using an excitation (or tipping) pulse followed by a series of refocusing pulses), the Optimized Refocusing Pulse Sequence (ORPS) (in which the refocusing pulses are less than 180°), a saturation recovery pulse sequence, and other pulse sequences. The NMR tool 120 collects measurements relating to spin relaxation time (e.g., T1, T2) distributions as a function of depth or position in the borehole. The NMR tool 120 has a magnet, magnetically permeable material, antenna, and supporting electronics. The permanent magnet in the tool causes the nuclear spins to build up into a cohesive magnetization. The T2 is measured through the decay of excited magnetization while T1 is measured by the buildup of magnetization.

The computer system 110 is configured to process (e.g., invert, transform, etc.) the acquired spin echo signals (or other NMR data) to obtain an NMR signal, such as a relaxation-time distribution (e.g., a distribution of transverse relaxation times T2, or a distribution of longitudinal relaxation times T1, or both). For example, the acquired spin echo signals are integrated using acquisition windows having different durations to generate the different NMR echo train signals. The relaxation-time distribution can be used to determine various physical properties of the formation by solving one or more inverse problems. In some cases, relaxation-time distributions are acquired for multiple logging points and used by the computer system 110 to train a model of the subsurface formation 850. In some cases, relaxation-time distributions are acquired for multiple logging points and used by the computer system 110 to predict properties of the subsurface formation 850. The relaxation data may also be referred to as NMR echo train data.

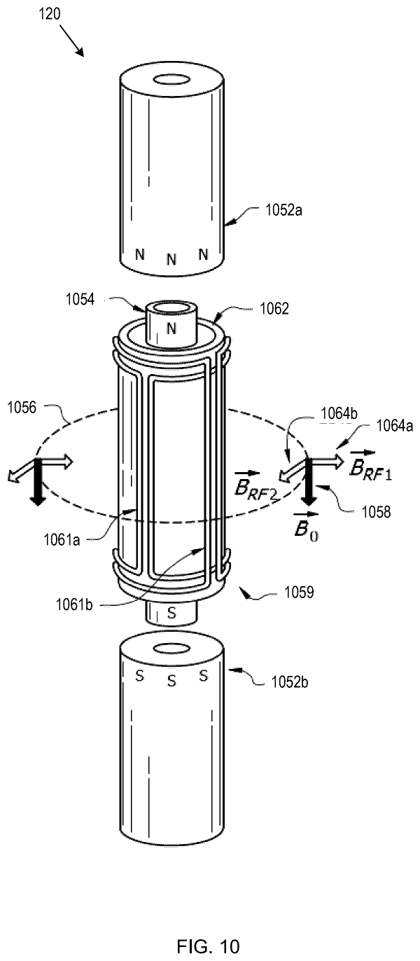

FIG. 10 is a diagram of an example NMR magnet and antenna(s) configuration of an NMR tool 120, according to some implementations. The example NMR tool 120 includes a magnet assembly that generates a static magnetic field to produce polarization, and an antenna assembly that generates a radio frequency (RF) magnetic field to excite nuclei and acquires NMR signals from the surrounding formation. In the non-limiting example shown in FIG. 10, the magnet assembly that includes the end piece magnets 1052a, 1052b and a central magnet 1054 generates the static magnetic field in the volume of investigation 1056. The poles of the central magnet 1054 (e.g., north (N) and south(S)) face the like poles of the proximal end piece magnets 1052a, 1052b. The central magnet 1054 is useful to shape and strengthen the static magnetic field in the volume of investigation 1056. In this example, the volume of investigation 1056 is approximately a cylindrical shell. In the volume of investigation 1056, the direction of the static magnetic field (shown as the solid black arrow 1058) is parallel to the longitudinal axis of the wellbore. In some examples, a magnet configuration with a bigger central magnet can be used to create a double pole strength and therefore increase the strength of the magnetic field (e.g., up to 100-150 Gauss or higher in some instances).

In the non-limiting example shown in FIG. 10, the antenna assembly 1059 includes two mutually orthogonal transversal dipole antennas 1061a, 1061b. In some instances, the NMR tool 120 can be implemented with a single transversal-dipole antenna. For example, one of the orthogonal transversal-dipole antennas 1061a, 1061b may be omitted from the antenna assembly 1059. The example orthogonal transversal-dipole antenna 1061a, 1061b shown in FIG. 10 are placed on an outer surface of a soft magnetic core 1062, which is useful for RF magnetic flux concentration. The antenna assembly 1059 generates two orthogonal RF magnetic fields 1064a (e.g., produced by the antenna 1061a) and 1064b (e.g., produced by the antenna 1061b). The two RF magnetic fields 1064a, 1064b have a phase shift of 90°. Accordingly, the RF magnetic fields 1064a, 1064b generate a circular polarized RF magnetic field to excite NMR in the surrounding formation more efficiently. It is also possible to only transmit with one antenna, even if a second antenna is included in the assembly. For example, the second antenna could be used only to receive NMR signals in this configuration. The same two orthogonal transversal-dipole antennas 1061a, 1061b are used to receive NMR signals from the surrounding formation. The received NMR signals are from induced currents from the NMR magnetization. The signals in the orthogonal transversal-dipole antennas 1061a, 1061b, may then be processed (e.g., by the computer system 110 of FIGS. 1 and 9-11) together in order to increase a signal-to-noise ratio (SNR) of the acquired NMR data.

In some implementations, the antenna assembly 1059 additionally or alternatively includes an integrated coil set that performs the operations of the two orthogonal transversal-dipole antennas 1061a, 1061b. For example, the integrated coil may be useful (e.g., instead of the two orthogonal transversal-dipole antennas 1061a, 1061b) to produce circular polarization and perform quadrature coil detection. Examples of integrated coil sets that can be adapted to perform such operations include multi-coil or complex single-coil arrangements, such as, for example, birdcage coils used for high-field magnetic resonance imaging (MRI). It is noted that the specific geometry and/or configuration of the NMR tool 120 is not necessarily limited to that shown in FIG. 10, and in other implementations, the NMR tool 120 may have different geometry and/or configurations.

Although some example well systems are described in FIGS. 1-10, it is noted, however, that the techniques and operations for performing NMR measurements and reducing motion artifacts from the NMR measurements described in FIGS. 1-10 can be used in any type of well system in the oil and gas industry.

As will be appreciated, aspects of the disclosure may be embodied as a system, method or program code/instructions stored in one or more machine-readable media. Accordingly, aspects may take the form of hardware, software (including firmware, resident software, micro-code, etc.), or a combination of software and hardware aspects that may all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine-readable medium(s) may be utilized. The machine-readable medium may be a machine-readable signal medium or a machine-readable storage medium. A machine-readable storage medium may be, for example, but not limited to, a system, apparatus, or device, that employs any one of or combination of electronic, magnetic, optical, electromagnetic, infrared, or semiconductor technology to store program code. More specific examples (a non-exhaustive list) of the machine-readable storage medium would include the following: a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine-readable storage medium may be any tangible medium that can contain, or store a program for use by or in connection with an instruction execution system, apparatus, or device. A machine-readable storage medium is not a machine-readable signal medium.

A machine-readable signal medium may include a propagated data signal with machine-readable program code embodied therein, for example, in baseband or as part of a carrier wave. Such a propagated signal may take any of a variety of forms, including, but not limited to, electro-magnetic, optical, or any suitable combination thereof. A machine-readable signal medium may be any machine-readable medium that is not a machine-readable storage medium and that can communicate, propagate, or transport a program for use by or in connection with an instruction execution system, apparatus, or device.

Program code embodied on a machine-readable medium may be transmitted using any appropriate medium, including but not limited to wireless, wireline, optical fiber cable, RF, etc., or any suitable combination of the foregoing.

Computer program code for carrying out operations for aspects of the disclosure may be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code may execute entirely on a stand-alone machine, may execute in a distributed manner across multiple machines, and may execute on one machine while providing results and or accepting input on another machine.

The program code/instructions may also be stored in a machine-readable medium that can direct a machine to function in a particular manner, such that the instructions stored in the machine-readable medium produce an article of manufacture including instructions which implement the function/act specified in the flowchart and/or block diagram block or blocks.

None of the implementations described herein may be performed exclusively in the human mind nor exclusively using pencil and paper. None of the implementations described herein may be performed without computerized components such as those described herein. Some implementations may perform additional operations, fewer operations, operations in parallel or in a different order, and some operations differently.

While the aspects of the disclosure are described with reference to various implementations and exploitations, it will be understood that these aspects are illustrative and that the scope of the claims is not limited to them. In general, techniques for performing NMR measurements and reducing motion artifacts from the NMR measurements as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

As used herein, the term “or” is inclusive unless otherwise explicitly noted. Thus, the phrase “at least one of A, B, or C” is satisfied by any element from the set {A, B, C} or any combination thereof, including multiples of any element.

Furthermore, unless otherwise specified, use of the terms “up,” “upper,” “upward,” “uphole,” “upstream,” or other like terms shall be construed as generally away from the bottom, terminal end of a well; likewise, use of the terms “down,” “lower,” “downward,” “downhole,” or other like terms shall be construed as generally toward the bottom, terminal end of the well, regardless of the wellbore orientation. Use of any one or more of the foregoing terms shall not be construed as denoting positions along a perfectly vertical axis. In some instances, a part near the end of the well can be horizontal or even slightly directed upwards. Unless otherwise specified, use of the term “subterranean formation” shall be construed as encompassing both areas below exposed earth and areas below earth covered by water such as ocean or fresh water.

### Example Embodiments

Example Embodiments can include the following:

Embodiment #1: A method for obtaining nuclear magnetic resonance (NMR) measurements of a subsurface formation in a well system, comprising: determining NMR echo data having motion artifacts in response to performing downhole NMR measurements using an NMR tool of the well system; determining a motion indicator based on echo measurements performed using two or more acquisition windows within each of a plurality of echo waveforms of the NMR echo data; determining motion data based on one or more non-NMR motion measurements obtained from one or more downhole well devices; selecting a motion hyperparameter based on the motion data and a motion correlation mechanism; and determining corrected NMR echo data having reduced motion artifacts based on the motion indicator and the selected motion hyperparameter.

Embodiment #2: The method of Embodiment #1, wherein determining the corrected NMR echo data having the reduced motion artifacts based on the motion indicator and the selected motion hyperparameter includes: determining a motion modifier based on the motion indicator and the selected motion hyperparameter; and determining the corrected NMR echo data having the reduced motion artifacts based on the motion modifier.

Embodiment #3: The method of Embodiment #1, wherein the motion correlation mechanism includes a motion correlation lookup table, and selecting the motion hyperparameter based on the motion data and the motion correlation mechanism includes: inputting the motion data into the motion correlation lookup table that correlates a plurality of motion data and a plurality of motion hyperparameters; and obtaining the selected motion hyperparameter that is correlated with the input motion data as an output of the motion correlation lookup table.

Embodiment #4: The method of Embodiment #3, further comprising creating the motion correlation lookup table of the motion correlation mechanism by using a plurality of known synthetic motion data and a plurality of known synthetic NMR echo data that yields a plurality of known results to determine a correlation between the plurality of known synthetic motion data and the plurality of motion hyperparameters.

Embodiment #5: The method of Embodiment #1, wherein the motion correlation mechanism includes a trained motion correlation learning machine that implements machine learning, and selecting the motion hyperparameter based on the motion data and the motion correlation mechanism includes: inputting the motion data into the trained motion correlation learning machine that correlates a plurality of motion data and a plurality of motion hyperparameters; and obtaining the selected motion hyperparameter that is correlated with the input motion data as an output of the trained motion correlation learning machine.

Embodiment #6: The method of Embodiment #5, further comprising training the trained motion correlation learning machine of the motion correlation mechanism by using a plurality of known synthetic motion data and a plurality of known synthetic NMR echo data that yields a plurality of known results to determine a correlation between the plurality of known synthetic motion data and the plurality of motion hyperparameters.

Embodiment #7: The method of Embodiment #1, wherein determining the motion indicator based on the echo measurements performed using the two or more acquisition windows within each of the plurality of echo waveforms of the NMR echo data includes: performing first echo measurements using a first acquisition window within each of the plurality of echo waveforms, and second echo measurements using a second acquisition window within each of the plurality of echo waveforms, wherein a first width of the first acquisition window is different than a second width of the second acquisition window; and determining the motion indicator based on the first echo measurements and the second echo measurements.

Embodiment #8: The method of Embodiment #1, wherein the motion data determined based on the one or more non-NMR motion measurements includes at least one of accelerometer measurements or acoustic measurements.

Embodiment #9: The method of Embodiment #1, further comprising: determining properties of the subsurface formation from the NMR echo data having the reduced motion artifacts.

Embodiment #10: The method of Embodiment #9, further comprising: modifying at least one of a well operation or a well operation attribute based on the determined properties of the subsurface formation.

Embodiment #11: A well system for obtaining nuclear magnetic resonance (NMR) measurements of a subsurface formation, the well system comprising: one or more processors; and a computer-readable storage medium having instructions stored thereon that are executable by the one or more processors to cause the well system to: determine NMR echo data having motion artifacts in response to performance of downhole NMR measurements using an NMR tool of the well system; determine a motion indicator based on echo measurements performed using two or more acquisition windows within each of a plurality of echo waveforms of the NMR echo data; determine motion data based on one or more non-NMR motion measurements obtained from one or more downhole well devices; select a motion hyperparameter based on the motion data and a motion correlation mechanism; and determine corrected NMR echo data having reduced motion artifacts based on the motion indicator and the selected motion hyperparameter.

Embodiment #12: The well system of Embodiment #11, wherein the instructions that cause the well system to determine the corrected NMR echo data having the reduced motion artifacts based on the motion indicator and the selected motion hyperparameter include instructions that cause the well system to: determine a motion modifier based on the motion indicator and the selected motion hyperparameter; and determine the corrected NMR echo data having the reduced motion artifacts based on the motion modifier.

Embodiment #13: The well system of Embodiment #11, wherein the motion correlation mechanism includes a motion correlation lookup table, and the instructions that cause the well system to select the motion hyperparameter based on the motion data and the motion correlation mechanism include instructions that cause the well system to: input the motion data into the motion correlation lookup table that correlates a plurality of motion data and a plurality of motion hyperparameters; and obtain the selected motion hyperparameter that is correlated with the input motion data as an output of the motion correlation lookup table.

Embodiment #14: The well system of Embodiment #11, wherein the motion correlation mechanism includes a trained motion correlation learning machine that implements machine learning, and the instructions that cause the well system to select the motion hyperparameter based on the motion data and the motion correlation mechanism include instructions that cause the well system to: input the motion data into the trained motion correlation learning machine that correlates a plurality of motion data and a plurality of motion hyperparameters; and obtain the selected motion hyperparameter that is correlated with the input motion data as an output of the trained motion correlation learning machine.

Embodiment #15: The well system of Embodiment #11, wherein the instructions that cause the well system to determine the motion indicator based on the echo measurements performed using the two or more acquisition windows within each of the plurality of echo waveforms of the NMR echo data include instructions that cause the well system to: perform first echo measurements using a first acquisition window within each of the plurality of echo waveforms, and second echo measurements using a second acquisition window within each of the plurality of echo waveforms, wherein a first width of the first acquisition window is different than a second width of the second acquisition window; and determine the motion indicator based on the first echo measurements and the second echo measurements.

Embodiment #16: A non-transitory computer-readable storage medium having instructions stored thereon that are executable by one or more processors of a well system, the well system for obtaining nuclear magnetic resonance (NMR) measurements of a subsurface formation, the instructions comprising: instructions for determining NMR echo data having motion artifacts in response to performing downhole NMR measurements using an NMR tool of the well system; instructions for determining a motion indicator based on echo measurements performed using two or more acquisition windows within each of a plurality of echo waveforms of the NMR echo data; instructions for determining motion data based on one or more non-NMR motion measurements obtained from one or more downhole well devices; instructions for selecting a motion hyperparameter based on the motion data and a motion correlation mechanism; and instructions for determining corrected NMR echo data having reduced motion artifacts based on the motion indicator and the selected motion hyperparameter.

Embodiment #17: The non-transitory computer-readable storage medium of Embodiment #16, wherein the instructions for determining the corrected NMR echo data having the reduced motion artifacts based on the motion indicator and the selected motion hyperparameter include: instructions for determining a motion modifier based on the motion indicator and the selected motion hyperparameter; and instructions for determining the corrected NMR echo data having the reduced motion artifacts based on the motion modifier.

Embodiment #18: The non-transitory computer-readable storage medium of Embodiment #16, wherein the motion correlation mechanism includes a motion correlation lookup table, and the instructions for selecting the motion hyperparameter based on the motion data and the motion correlation mechanism include: instructions for inputting the motion data into the motion correlation lookup table that correlates a plurality of motion data and a plurality of motion hyperparameters; and instructions for obtaining the selected motion hyperparameter that is correlated with the input motion data as an output of the motion correlation lookup table.

Embodiment #19: The non-transitory computer-readable storage medium of Embodiment #16, wherein the motion correlation mechanism includes a trained motion correlation learning machine that implements machine learning, and the instructions for selecting the motion hyperparameter based on the motion data and the motion correlation mechanism include: instructions for inputting the motion data into the trained motion correlation learning machine that correlates a plurality of motion data and a plurality of motion hyperparameters; and instructions for obtaining the selected motion hyperparameter that is correlated with the input motion data as an output of the trained motion correlation learning machine.

Embodiment #20: The non-transitory computer-readable storage medium of Embodiment #16, wherein the instructions for determining the motion indicator based on the echo measurements performed using the two or more acquisition windows within each of the plurality of echo waveforms of the NMR echo data include: instructions for performing first echo measurements using a first acquisition window within each of the plurality of echo waveforms, and second echo measurements using a second acquisition window within each of the plurality of echo waveforms, wherein a first width of the first acquisition window is different than a second width of the second acquisition window; and instructions for determining the motion indicator based on the first echo measurements and the second echo measurements.

What is claimed is:

1. A method for obtaining nuclear magnetic resonance (NMR) measurements of a subsurface formation in a well system, comprising:
determining NMR echo data having motion artifacts in response to performing downhole NMR measurements using an NMR tool of the well system;
determining a motion indicator based on echo measurements performed using two or more acquisition windows within each of a plurality of echo waveforms of the NMR echo data;
determining motion data based on one or more non-NMR motion measurements obtained from one or more downhole well devices;
selecting a motion hyperparameter based on the motion data and a motion correlation mechanism; and
determining corrected NMR echo data having reduced motion artifacts based on the motion indicator and the selected motion hyperparameter.

2. The method of claim 1, wherein determining the corrected NMR echo data having the reduced motion artifacts based on the motion indicator and the selected motion hyperparameter includes:
determining a motion modifier based on the motion indicator and the selected motion hyperparameter; and
determining the corrected NMR echo data having the reduced motion artifacts based on the motion modifier.

3. The method of claim 1, wherein the motion correlation mechanism includes a motion correlation lookup table, and selecting the motion hyperparameter based on the motion data and the motion correlation mechanism includes:
inputting the motion data into the motion correlation lookup table that correlates a plurality of motion data and a plurality of motion hyperparameters; and
obtaining the selected motion hyperparameter that is correlated with the input motion data as an output of the motion correlation lookup table.

4. The method of claim 3, further comprising creating the motion correlation lookup table of the motion correlation mechanism by using a plurality of known synthetic motion data and a plurality of known synthetic NMR echo data that yields a plurality of known results to determine a correlation between the plurality of known synthetic motion data and the plurality of motion hyperparameters.

5. The method of claim 1, wherein the motion correlation mechanism includes a trained motion correlation learning machine that implements machine learning, and selecting the motion hyperparameter based on the motion data and the motion correlation mechanism includes:
inputting the motion data into the trained motion correlation learning machine that correlates a plurality of motion data and a plurality of motion hyperparameters; and
obtaining the selected motion hyperparameter that is correlated with the input motion data as an output of the trained motion correlation learning machine.

6. The method of claim 5, further comprising training the trained motion correlation learning machine of the motion correlation mechanism by using a plurality of known synthetic motion data and a plurality of known synthetic NMR echo data that yields a plurality of known results to determine a correlation between the plurality of known synthetic motion data and the plurality of motion hyperparameters.

7. The method of claim 1, wherein determining the motion indicator based on the echo measurements performed using the two or more acquisition windows within each of the plurality of echo waveforms of the NMR echo data includes:
performing first echo measurements using a first acquisition window within each of the plurality of echo waveforms, and second echo measurements using a second acquisition window within each of the plurality of echo waveforms, wherein a first width of the first acquisition window is different than a second width of the second acquisition window; and
determining the motion indicator based on the first echo measurements and the second echo measurements.

8. The method of claim 1, wherein the motion data determined based on the one or more non-NMR motion measurements includes at least one of accelerometer measurements or acoustic measurements.

9. The method of claim 1, further comprising:
determining properties of the subsurface formation from the NMR echo data having the reduced motion artifacts.

10. The method of claim 9, further comprising:
modifying at least one of a well operation or a well operation attribute based on the determined properties of the subsurface formation.

11. A well system for obtaining nuclear magnetic resonance (NMR) measurements of a subsurface formation, the well system comprising:
one or more processors; and
a computer-readable storage medium having instructions stored thereon that are executable by the one or more processors to cause the well system to:
determine NMR echo data having motion artifacts in response to performance of downhole NMR measurements using an NMR tool of the well system;
determine a motion indicator based on echo measurements performed using two or more acquisition windows within each of a plurality of echo waveforms of the NMR echo data;
determine motion data based on one or more non-NMR motion measurements obtained from one or more downhole well devices;
select a motion hyperparameter based on the motion data and a motion correlation mechanism; and
determine corrected NMR echo data having reduced motion artifacts based on the motion indicator and the selected motion hyperparameter.

12. The well system of claim 11, wherein the instructions that cause the well system to determine the corrected NMR echo data having the reduced motion artifacts based on the motion indicator and the selected motion hyperparameter include instructions that cause the well system to:
determine a motion modifier based on the motion indicator and the selected motion hyperparameter; and
determine the corrected NMR echo data having the reduced motion artifacts based on the motion modifier.

13. The well system of claim 11, wherein the motion correlation mechanism includes a motion correlation lookup table, and the instructions that cause the well system to select the motion hyperparameter based on the motion data and the motion correlation mechanism include instructions that cause the well system to:
input the motion data into the motion correlation lookup table that correlates a plurality of motion data and a plurality of motion hyperparameters; and
obtain the selected motion hyperparameter that is correlated with the input motion data as an output of the motion correlation lookup table.

14. The well system of claim 11, wherein the motion correlation mechanism includes a trained motion correlation learning machine that implements machine learning, and the instructions that cause the well system to select the motion hyperparameter based on the motion data and the motion correlation mechanism include instructions that cause the well system to:
input the motion data into the trained motion correlation learning machine that correlates a plurality of motion data and a plurality of motion hyperparameters; and
obtain the selected motion hyperparameter that is correlated with the input motion data as an output of the trained motion correlation learning machine.

15. The well system of claim 11, wherein the instructions that cause the well system to determine the motion indicator based on the echo measurements performed using the two or more acquisition windows within each of the plurality of echo waveforms of the NMR echo data include instructions that cause the well system to:
perform first echo measurements using a first acquisition window within each of the plurality of echo waveforms, and second echo measurements using a second acquisition window within each of the plurality of echo waveforms, wherein a first width of the first acquisition window is different than a second width of the second acquisition window; and
determine the motion indicator based on the first echo measurements and the second echo measurements.

16. A non-transitory computer-readable storage medium having instructions stored thereon that are executable by one or more processors of a well system, the well system for obtaining nuclear magnetic resonance (NMR) measurements of a subsurface formation, the instructions comprising:
instructions for determining NMR echo data having motion artifacts in response to performing downhole NMR measurements using an NMR tool of the well system;
instructions for determining a motion indicator based on echo measurements performed using two or more acquisition windows within each of a plurality of echo waveforms of the NMR echo data;
instructions for determining motion data based on one or more non-NMR motion measurements obtained from one or more downhole well devices;
instructions for selecting a motion hyperparameter based on the motion data and a motion correlation mechanism; and
instructions for determining corrected NMR echo data having reduced motion artifacts based on the motion indicator and the selected motion hyperparameter.

17. The non-transitory computer-readable storage medium of claim 16, wherein the instructions for determining the corrected NMR echo data having the reduced motion artifacts based on the motion indicator and the selected motion hyperparameter include:
instructions for determining a motion modifier based on the motion indicator and the selected motion hyperparameter; and
instructions for determining the corrected NMR echo data having the reduced motion artifacts based on the motion modifier.

18. The non-transitory computer-readable storage medium of claim 16, wherein the motion correlation mechanism includes a motion correlation lookup table, and the instructions for selecting the motion hyperparameter based on the motion data and the motion correlation mechanism include:
instructions for inputting the motion data into the motion correlation lookup table that correlates a plurality of motion data and a plurality of motion hyperparameters; and
instructions for obtaining the selected motion hyperparameter that is correlated with the input motion data as an output of the motion correlation lookup table.

19. The non-transitory computer-readable storage medium of claim 16, wherein the motion correlation mechanism includes a trained motion correlation learning machine that implements machine learning, and the instructions for selecting the motion hyperparameter based on the motion data and the motion correlation mechanism include:
instructions for inputting the motion data into the trained motion correlation learning machine that correlates a plurality of motion data and a plurality of motion hyperparameters; and
instructions for obtaining the selected motion hyperparameter that is correlated with the input motion data as an output of the trained motion correlation learning machine.

20. The non-transitory computer-readable storage medium of claim 16, wherein the instructions for determining the motion indicator based on the echo measurements performed using the two or more acquisition windows within each of the plurality of echo waveforms of the NMR echo data include:
instructions for performing first echo measurements using a first acquisition window within each of the plurality of echo waveforms, and second echo measurements using a second acquisition window within each of the plurality of echo waveforms, wherein a first width of the first acquisition window is different than a second width of the second acquisition window; and
instructions for determining the motion indicator based on the first echo measurements and the second echo measurements.
